(19) United States
(12) Patent Application Publication
(10) Pub. No.: US 2025/0185422 A1
(43) Pub. Date: Jun. 5, 2025

(54) OPTOELECTRONIC DEVICE WITH THREE-ELECTRODE DIODES

(71) Applicant: Commissariat à l'Énergie Atomique et aux Énergies Alternatives, Paris (FR)

(72) Inventors: Julia Simon, Grenoble (FR); Patrick Le Maitre, Grenoble (FR)

(73) Assignee: Commissariat à l'Énergie Atomique et aux Énergies Alternatives, Paris (FR)

(21) Appl. No.: 18/954,803

(22) Filed: Nov. 21, 2024

(30) Foreign Application Priority Data
Dec. 1, 2023 (FR) 2313439

(51) Int. Cl. H01L 33/38; H01L 31/0216; H01L 31/0224; H01L 33/42; H01L 33/44

(52) U.S. Cl. CPC H10H 20/8312; H10F 77/206; H10F 77/244; H10F 77/306; H10H 20/833; H10H 20/84; H10H 20/032

(57) ABSTRACT

Optoelectronic device including: a plurality of diodes each including a portion of a stack of first and second semiconductor layers doped according to opposite types, a portion of the first layer of each diode being coupled to a first electrode; trenches running through the stack; a conductive layer arranged against side walls of the trenches, insulated from the stack, coupled to the second electrodes and which is interrupted in such a way that portions of the conductive layer arranged around each of the diodes are insulated from other portions of the conductive layer arranged around the other diodes; conductive portions arranged in the trenches, insulated from the electrically conductive layer and coupled to one another and to a third electrode; bottom walls of the trenches being formed at least by the second electrodes.

### CROSS REFERENCE TO RELATED APPLICATIONS

This application claims priority to French application number 2313439, filed Dec. 1, 2023, the contents of which is incorporated by reference in its entirety.

### TECHNICAL FIELD

The present disclosure generally concerns the field of optoelectronic devices comprising light-emitting diodes (also called LEDs) used, for example, for the forming of any light-emitting device (displays, projectors, video walls, etc.), and/or of photodiodes.

### PRIOR ART

Document EP 2 960 951 A1 describes an optoelectronic device of LED or photodiode type comprising, in addition to the two electrodes each coupled to one of the semiconductors of a p-n junction, a third electrode in the form of a grid or of a Schottky contact. This third electrode enables, by generating a lateral electric field enabling to increase the EQE (external quantum efficiency), to overcome the problem of a lack of charge carriers in certain semiconductor materials due to too high an energy of activation of the dopants in these semiconductor materials, such as for example in materials with large gaps such as diamond or epitaxial structures based on AlGaN used in particular for LEDs emitting in the UV range. When the device comprises a plurality of LEDs and/or photodiodes, the third electrode of the LEDs and/or photodiodes is common and distributed for all these LEDs and/or photodiodes, for example in the form of trenches formed around the p-n junctions or through the p-n junctions of the LEDs and/or photodiodes.

A disadvantage of such an optoelectronic device is that the electrical contacting between the electrodes requires a very precise alignment when this device is formed with small dimensions. It is possible to facilitate this contacting by forming the device with larger dimensions, and thus to the detriment of the compactness of the device.

Document WO 2019/141948 A1 describes an optoelectronic device of LED or photodiode type with three electrodes, in which the third electrode is electrically coupled to the cathode. Thus, the electrical contacting is facilitated due to the fact that it is no longer necessary to electrically access this third electrode and the cathode separately. A disadvantage of this solution is that this architecture does not enable to control the electrical potentials applied to the third electrodes independently of those applied to the cathodes.

### SUMMARY OF THE INVENTION

There thus exists a need to provide an optoelectronic device comprising three-electrode diodes which does not have the disadvantages of existing solutions.

An embodiment overcomes all or part of the disadvantages of known solutions and provides an optoelectronic device comprising at least:
a plurality of diodes each comprising a portion of a stack of at least a first and a second semiconductor layers doped according to opposite conductivity types, a portion of the first semiconductor layer of each diode being electrically coupled to a first electrode arranged under said portion of the first semiconductor layer;
trenches running through the stack, separating the diodes from one another and from which second electrodes are electrically accessible;
an electrically conductive layer arranged at least against side walls of the trenches, electrically insulated from the stack, electrically coupled to the second electrodes and which is interrupted in such a way that portions of the electrically conductive layer arranged around each of the diodes are electrically insulated from other portions of the electrically conductive layer arranged around the other diodes;
electrically conductive portions arranged in the trenches, electrically insulated from the electrically conductive layer and electrically coupled to one another and to at least a third electrode.

According to a specific embodiment, the electrically conductive layer is interrupted at bottom walls of the trenches.

According to a specific embodiment, bottom walls of the trenches are at least partly formed by the second electrodes.

According to a specific embodiment, the electrically conductive portions are electrically coupled to the portions of the second semiconductor layer of at least part of the diodes corresponding to LEDs.

According to a specific embodiment, the electrically conductive portions are electrically coupled to the portions of the second semiconductor layer of the LEDs by at least one electrically conductive and optically transparent layer arranged on the stack and on the electrically conductive portions.

According to a specific embodiment, the electrically conductive and optically transparent layer is electrically insulated from the electrically conductive layer by dielectric portions arranged between the electrically conductive layer and the electrically conductive and optically transparent layer.

According to a specific embodiment, the electrically conductive portions are electrically insulated from the electrically conductive layer by at least a first dielectric layer arranged between the electrically conductive portions and the electrically conductive layer.

According to a specific embodiment, the third electrode is arranged at an edge of the optoelectronic device.

According to a specific embodiment:
each first electrode is arranged between two second electrodes to which are electrically coupled the portions of the electrically conductive layer located around the diode having the portion of its first semiconductor layer electrically coupled to said first electrode, and
the optoelectronic device comprises a plurality of third electrodes, each electrically coupled to one of the electrically conductive portions and arranged between two second electrodes, each electrically coupled to portions of the electrically conductive layer located around different diodes.

According to a specific embodiment, the device comprises a plurality of third electrodes, each electrically coupled to one of the electrically conductive portions, each of the first electrodes being disposed between one of the second electrodes and one of the third electrodes, and each of the third electrodes is arranged between one of the first electrodes and one of the second electrodes.

According to a specific embodiment, portions of the electrically conductive layer arranged around at least part of the diodes corresponding to photodiodes are electrically coupled to the portions of the second semiconductor layer of the photodiodes.

According to a specific embodiment, the portions of the electrically conductive layer arranged around the photodiodes are electrically coupled to the portions of the second semiconductor layer of the photodiodes by at least one electrically conductive and optically transparent layer arranged on the stack and on the portions of the electrically conductive layer arranged around the photodiodes.

According to a specific embodiment, the device further comprises a second dielectric layer arranged between the electrically conductive layer and the stack.

There is also provided a method of manufacturing an optoelectronic device, comprising at least the steps of:
forming of a stack of at least a first and a second semiconductor layer doped according to opposite conductivity types;
forming of trenches running through the stack, separating from one another diodes, each comprising a portion of the stack and providing access to second electrodes, a portion of the first semiconductor layer of each diode being electrically coupled to a first electrode arranged under said portion of the first semiconductor layer;
forming of an electrically conductive layer arranged at least against side walls of the trenches, electrically insulated from the stack, electrically coupled to the second electrodes and which is interrupted in such a way that portions of the electrically conductive layer arranged around each of the diodes are electrically insulated from the portions of the electrically conductive layer located around the other diodes;
forming of electrically conductive portions arranged in the trenches, electrically insulated from the electrically conductive layer and electrically coupled to each other and to at least a third electrode.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows an example of an optoelectronic device according to a first embodiment;

FIG. 2, FIG. 3, FIG. 4, FIG. 5, FIG. 6, FIG. 7, FIG. 8, and FIG. 9 show steps of a method of manufacturing an optoelectronic device according to the first embodiment;

FIG. 10 shows an example of an optoelectronic device according to a second embodiment;

FIG. 11, FIG. 12, FIG. 13, and FIG. 14 show steps of a method of manufacturing an optoelectronic device according to the second embodiment;

FIG. 15 shows an example of an optoelectronic device according to a first alternative embodiment; and

FIG. 16 shows an example of an optoelectronic device according to a second alternative embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, different elements of the device (for example the integrated control circuit) and different steps of the device forming method (deposition, photolithography, etching, etc.) are not detailed. Those skilled in the art will be capable of designing these elements and of implementing these steps in detail based on the description given herein.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, “on”, “under”, etc., or orientation qualifiers, such as “horizontal”, “vertical”, etc., reference is made unless otherwise specified to the orientation of the drawings in a normal position of use.

Unless specified otherwise, the expressions “about”, “approximately”, “substantially”, and “in the order of” signify plus or minus 10%, preferably of plus or minus 5%.

All throughout the document, the term “diode” is used to designate a light-emitting diode or a photodiode.

All throughout the document, the term “LED” designates a LED or a micro-LED.

All throughout the document, the term “layer” is used to designate a layer comprising a single material or a plurality of materials arranged one against the other, that is, a stack.

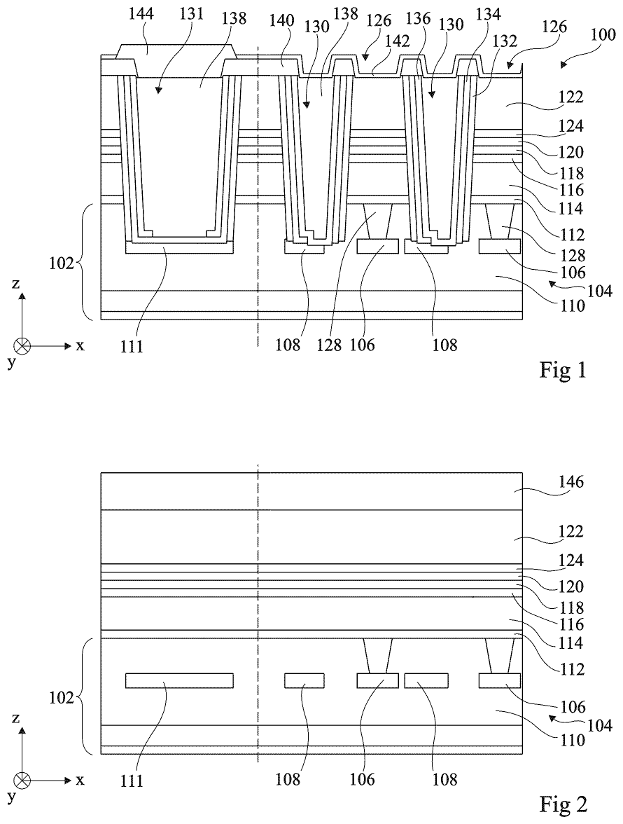

In FIGS. 1 to 14, dotted lines are shown to illustrate the fact that the elements of device 100 shown on either side of these dotted lines are not necessarily arranged directly next to one another.

An example of an optoelectronic device 100 according to a first embodiment is described hereafter in relation with FIG. 1.

In the described example of embodiment, device 100 comprises an integrated control circuit 102 comprising at least, in a metallization level 104, first electrodes 106 and second electrodes 108. Circuit 102, which corresponds for example to an ASIC (Application-specific integrated circuit), comprises electronic components enabling in particular to implement different functions of control of diodes of device 100, these functions not being detailed herein. In FIG. 1, only level 104 is shown, although circuit 102 may comprise a plurality of stacked metallization levels providing the electrical connections of the electronic components of circuit 102.

In the example of FIG. 1, level 104 comprises a dielectric layer 110 having electrodes 106, 108 arranged therein. This dielectric layer 110 comprises, for example, SiO₂ and its thickness (dimension parallel to the Z axis in FIG. 1) is, for example, equal to 1 μm.

In the described example of embodiment, the first electrodes 106 correspond to anodes of the diodes of device 100, and the second electrodes 108 correspond to electrodes having gates surrounding the p-n junctions of the diodes of device 100 electrically coupled thereto. In FIG. 1, only two first electrodes 106 and two second electrodes 108 are shown. The total number of first and second electrodes 106, 108 of device 100 depends in particular on the number of diodes of device 100. As a variant, other configurations of first and second electrodes 106, 108 are possible.

In the described example of embodiment, circuit 102 also comprises, in level 104, at least a third electrode 111 used as a cathode for the diodes of device 100. In the example of FIG. 1, device 100 comprises a third electrode 111 forming a cathode common to the diodes of device 100. Further, in the described example of embodiment, the third electrode 111 is arranged at the periphery of device 100, that is, at an edge of device 100 and not within the diode assembly of device 100.

Electrodes 106, 108, 111 comprise, for example, a metallic material such as aluminum or copper.

In the described example, device 100 further comprises a plurality of metal layers stacked on integrated circuit 102. In the example of FIG. 1, these metal layers correspond to:
a first stack 112 of Ti/TiN, comprising for example a titanium thickness equal to 5 nm and a TiN thickness equal to 30 nm;
a titanium layer 114 for example having a thickness equal to 500 nm;
a second stack 116 of Ti/TiN, for example comprising a titanium thickness of 10 nm and a TiN thickness of 40 nm.

In this example of embodiment of device 100, these metal layers 112, 114, 116 are used in particular for the implementation, on manufacturing of device 100, of a direct metal-to-metal bonding between, on the one hand, the first stack 112 and a portion of layer 114 formed on circuit 102, and, on the other hand, the second stack 116 and another portion of layer 114 formed on a stack of layers used for the manufacturing of the diodes of device 100. As a variant, these metal layers may be different from those described in the example of FIG. 1, in terms of number of layers, thicknesses, materials, etc.

In the described example, an AlSi layer 118 is arranged on the second stack 116, and for example has a thickness equal to 100 nm.

Device 100 further comprises a plurality of diodes 126, each comprising a portion of a stack of at least a first and a second semiconductor layers 120, 122 doped according to opposite conductivity types. In the example of FIG. 1, the semiconductor of first layer 120 is p-doped, and the semiconductor of second layer 122 is n-doped. Further, in this example, this semiconductor stack further comprises an active area 124 arranged between layers 120, 122 and comprising one or a plurality of emissive or receiver (optically absorbing) layers, each forming a quantum well and each arranged between two barrier layers. All the layers of active area 124, that is, the emitter/receiver layer(s) and the barrier layers, comprise intrinsic, that is, unintentionally doped, semiconductor materials (with a residual donor concentration n_{nid} for example in the range from approximately 10¹⁵ to 10¹⁸ donors/cm³). The semiconductor stack is arranged, for example bonded, on level 104 (with, in the example of FIG. 1, layers 112 to 118 arranged between level 104 and the semiconductor stack) and here forms, for each diode 126, a p-i-n junction.

The semiconductor materials of layers 120, 122, 124 comprise, for example, gallium and/or aluminum and/or indium nitride. According to an embodiment, this semiconductor stack is such that it comprises:
a first layer 120 comprising p-GaN and having a thickness, for example, equal to 120 nm;
a second layer 122 comprising n-GaN and having a thickness, for example, equal to 500 nm;
an active area 124 comprising one or a plurality of emissive InGaN layers and GaN barrier layers, having a thickness for example in the range from 50 nm to 80 nm.

According to another example of embodiment, the first and second layers 120, 122 may comprise AlGaN and the layer(s) of active area 124 may comprise GaN.

As a variant, other families of semiconductor materials may be used for the forming of layers 120, 122, 124, for example arsenide or phosphide semiconductors.

In the first embodiment, all the diodes 126 of device 100 correspond to LEDs.

In the example of FIG. 1, two diodes 126 are shown, each comprising a portion of the stack of layers 120, 122, 124. A portion of the first semiconductor layer 120 of each diode 126 is electrically coupled to one of the first electrodes 106 arranged under this portion of the first semiconductor layer 120, this electrical coupling being achieved via an electrically conductive via 128 formed between the first electrode 106 and the portions of the metal layers 112, 114, 116 arranged on this first electrode 106 and which are in contact with this portion of the first semiconductor layer 120.

As a variant, it is possible for the interface between circuit 102 and the semiconductor stack of diodes 126, or between level 104 and the semiconductor stack of diodes 126, to be formed by layers different from layers 112 to 118, according in particular to the techniques implemented for the manufacturing of device 100.

Device 100 further comprises trenches 130 running through the semiconductor stack (that is, layers 120, 122, and 124), surrounding and separating diodes 126 from one another, and having bottom walls at least partly formed by the second electrodes 108. In the described embodiment, these trenches 130 further run through layers 112, 114, 116, and 118, as well as through a portion of dielectric layer 110, until reaching the second electrodes 108.

Trenches 130 are for example designed in such a way as to form, through the different layers in which these trenches 130 are formed, a grid delimiting diodes 126, having a cross-section, in a plane parallel to the main planes in which these different layers extend (plane parallel to the plane (X,Y) shown in FIG. 1), with a square, hexagonal, or rectangular shape. The dimension of one of the trenches 130 between two adjacent diodes 126, that is, the width of each trench 130 (which corresponds to the dimension of trench 130 parallel to the X axis in FIG. 1), is for example equal to approximately 1 μm.

In the described embodiment, another trench 131 runs through the semiconductor stack as well as through layers 112, 114, 116, and 118 and a portion of dielectric layer 110. In this example, this trench 131 has a bottom wall emerging onto the third electrode 111 and enables to make electrical contact with the third electrode 111.

In the described example, the side walls, or flanks, of trenches 130, 131 are covered with a dielectric layer 132 acting as a passivation layer and comprising, for example, at least one of the following materials: alumina, AlN, SiO₂, SiN.

In the described example, dielectric layer 132 is covered, on the side walls of trenches 130, 131, with an electrically conductive layer 134. This electrically conductive layer 134 is also arranged against the bottom walls of trenches 130, 131. In the example of FIG. 1, electrically conductive layer 134 is thus electrically insulated from the stack of layers present on circuit 102 by dielectric layer 132. Further, the electrically conductive layer 134 is electrically coupled to the second electrodes 108 and is interrupted in such a way as portions of this electrically conductive layer 134 arranged around each of diodes 126 are electrically insulated from other portions of this electrically conductive layer 134 arranged around the other diodes 126. In the described example, electrically conductive layer 134 is interrupted at the bottom walls of trenches 130. In the example of FIG. 1, electrically conductive layer 134 is not interrupted in trench 131.

According to an example of embodiment, electrically conductive layer 134 comprises at least one metal. This metal may, for example, enable to reflect light, particularly in the visible range, which enables light laterally emitted by diodes 126 to reflect against the electrically conductive layer 134 and thus to avoid disturbing the neighboring diodes 126.

In the described example, the electrically conductive layer 134 is covered with another dielectric layer 136 which also covers the portions of the dielectric layer 132 located at the interrupted portions of electrically conductive layer 134 (at the bottom walls of trenches 130 in the example of FIG. 1). This other dielectric layer 136 comprises, for example, SiO₂ or alumina. In the example of FIG. 1, dielectric layer 136 is interrupted at the bottom wall of trench 131, so that electrically conductive layer 134 is electrically accessible from the bottom of trench 131.

In the described example, the rest of the volume of trenches 130 not occupied by layers 132, 134, and 136 is filled by electrically conductive portions 138, which are electrically insulated from electrically conductive layer 134 by dielectric layer 136. Although this is not shown in FIG. 1, the electrically conductive portions 138 are here electrically coupled to each other due to the grid-like shape of trenches 130. In an example of embodiment, each of the electrically conductive portions 138 comprises a stack of a plurality of materials, for example a stack of Ti/TiN and of copper. In trench 131, electrically conductive portion 138 is electrically coupled to electrically conductive layer 134, and thus also to third electrode 111.

In the described example of embodiment, device 100 further comprises dielectric portions 140, for example comprising SiN, extending over the tops of the portions of electrically conductive layer 134. Further, device 100 comprises an electrically conductive and optically transparent layer 142 arranged on an upper surface of device 100 and which electrically couples the electrically conductive portions 138 to one another and to the portions of the second semiconductor layer 122 of diodes 126. This layer 142 is electrically insulated from the electrically conductive layer 134 by dielectric portions 140. The electrically conductive and optically transparent layer 142 may comprise a transparent conductive oxide, such as ITO, to allow a light emission from diodes 126 therethrough. Layer 142 also ensures the spreading of the current over the distance between the semiconductor of second layer 122 and electrically conductive portions 138.

In the described example of embodiment, the metal filling of trenches 130, 131 allows the electrical coupling between the portions of the second semiconductor layer 122 of diodes 126 and the third electrode 111, which corresponds to the common cathode of diodes 126. In the example shown in FIG. 1, device 100 further comprises a connection pad 144 arranged on the electrically conductive portion 138 arranged in trench 131, and used as an electrical access to the common cathode of diodes 126.

Thus, the device 100 according to the first embodiment comprises diodes 126 controllable independently of one another and addressable by electrical control potentials applied by circuit 102 to the anodes corresponding to the first electrodes 106. Further, the gates formed by the portions of electrically conductive layer 134 around the semiconductor stacks of diodes 126 are independently controllable and addressable by electrical control potentials applied by circuit 102 to the second electrodes 108. The application of an electrical potential to these gates may modify the distribution of carriers on the side flanks of the P- or N-doped semiconductor (depending on the potential applied), which enables to increase the light emission efficiency of diodes 126. During the application of these electrical potentials on these gates, no current flows through these gates.

Advantageously, the thickness of dielectric layer 132 may be selected such that it is sufficient to prevent a breakdown when an electrical potential is applied to the gate of diodes 126, without however being too thick, in order to maximize the field effect applied via the gate of diodes 126. As an example, the thickness of this dielectric layer 132 is for example in the range from 10 nm to 60 nm, according to the dielectric characteristics of the material(s) of this layer 132.

Advantageously, the thickness of dielectric layer 136 may be selected in such a way that it is sufficient to avoid a breakdown due to the electrical potentials applied to the gates of diodes 126 and to the electrical reference potential, for example, the ground, applied to the cathode. For example, when the potential difference between the electrically conductive layer 134 and the electrically conductive portions 138 is in the order of 1 V, dielectric layer 136 may comprise alumina and have a thickness equal to approximately 10 nm.

The side flanks of trenches 130, 131 may be perpendicular to the surface of circuit 102 to which the semiconductor stack is bonded, or form an angle such that the width of trenches 130, 131 at the upper surface of device 100 (surface at which dielectric portions 140 and electrically conductive and optically transparent layer 142 are present) is greater than the width of trenches 130, 131 at circuit 102, that is, at dielectric layer 110 in the example of FIG. 1. Such a difference in the width of trenches 130, 131 can facilitate the implementation of the depositions of the materials in trenches 130, 131.

The described device 100 thus comprises a compact assembly of three-electrode diodes 126, having its diodes 126 individually controllable due to the electrical independence of the anodes and of the gates of these diodes 126.

The structure of device 100 can allow its forming by a monolithic integration, directly on circuit 102, of the junctions forming diodes 126 with no critical alignment, due to the fact that the singulation of diodes 126 (corresponding to the forming of trenches 130) is carried out after the bonding of semiconductor layers to circuit 102.

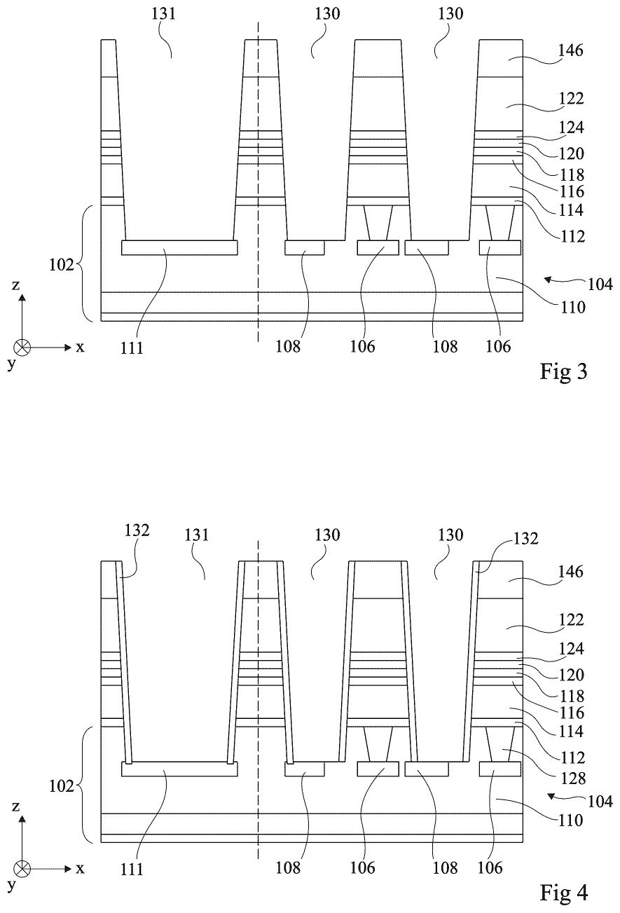

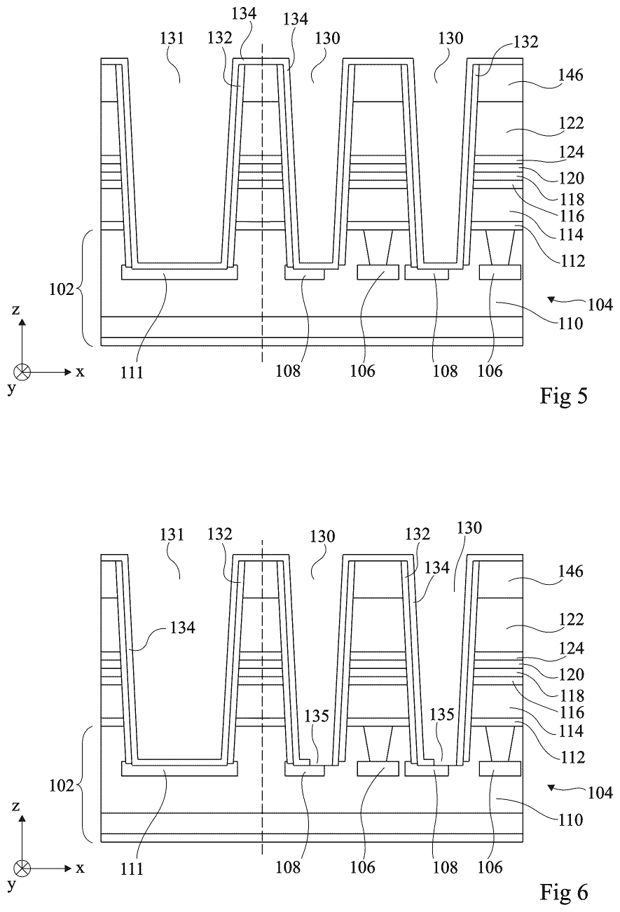

An example of a method of forming the device 100 such as previously described in relation with FIG. 1 is described hereafter in relation with FIGS. 2 to 9.

Integrated circuit 102 is first formed from a semiconductor substrate, for example by implementing conventional steps of microelectronics (deposition, lithography, etching, etc.) to form the electronic components of this integrated circuit 102, as well as the metallization levels (BEOL), including metallization level 104. The first stack 112 and a portion of layer 114 are also formed on level 104 in anticipation of a future direct metal-to-metal bonding with the semiconductor stack intended for the forming of diodes 126.

In the described example, the semiconductor stack of layers 124, 122, and 120, as well as layer 118, the second stack 116, and a portion of layer 114, are formed on another substrate (not shown). Layers 124, 122, and 120 are for example formed by epitaxy. One or a plurality of buffer layers may be present on this other substrate to facilitate the growth of layers 124, 122, and 120.

A direct metal-to-metal bonding may then be implemented to bond the two portions of layer 114 to each other, after which the substrate having been used for the growth of layers 124, 122, and 120 may be removed. The possible buffer layer(s) interposed between the substrate and layer 124 may also be removed, for example by thinning and etching.

As a variant, other types of bonding may be implemented to bond circuit 102 to the semiconductor stack from which diodes 126 will be formed.

In the described embodiment, a dielectric hard mask 146 is then formed, for example by deposition, on semiconductor layer 122. According to an example, dielectric hard mask 146 may comprise SiO₂ and/or SiN. The thickness of dielectric hard mask 146 is here selected to be sufficient to be able to etch trenches 130, 131 to reach electrodes 106, 108, 111. The structure obtained at this stage of the method is shown in FIG. 2.

Trenches 130, 131 are then formed through the semiconductor stack all the way to electrodes 111, 106, and 108. In the described example of embodiment, a lithography and an etching may then be implemented, by using dielectric hard mask 146, to form trenches 130, 131 through the layers present on electrodes 106, 108, and 111. The implemented etching may make judicious use of a barrier layer comprising, for example, TiN and/or SiN and present on the metal level of electrodes 106, 108, 111. The use of such a barrier layer enables for possible thickness variations of the etched materials not to impact the final depth of trenches 130, 131. This etching of trenches 130, 131 down to the metallization level comprising electrodes 106, 108, 111 then enables to make the different contacts. The structure obtained at this stage of the method is shown in FIG. 3.

In the described example of embodiment, dielectric layer 132 is then deposited in trenches 130, 131, covering the side walls and the bottom walls of these trenches 130, 131, and also on dielectric hard mask 146. An anisotropic etching may then be implemented to remove the portions of dielectric layer 132 arranged on the bottom walls of trenches 130, 131, as well as those resting on dielectric hard mask 146. The remaining portions of dielectric layer 132 form dielectric spacers covering the flanks, or side walls, of diodes 126. The structure obtained at this stage of the method is shown in FIG. 4.

Electrically conductive layer 134 is then deposited on the resulting structure, thus covering the bottom walls of trenches 130, 131, dielectric hard mask 146, as well as the remaining portions of dielectric layer 132 arranged against the side walls of trenches 130, 131. In trenches 130, electrically conductive layer 134 is in electrical contact with the second electrodes 108, that is, those intended to form the gates of diodes 126 in the described example. Prior to this deposition, one or a plurality of steps of preparation of the surfaces on which the electrically conductive layer 134 is intended to be deposited may be implemented, for example to remove a possible native metal oxide present on these surfaces. The structure obtained at this stage of the method is shown in FIG. 5.

A local etch step may then be implemented to remove certain portions of electrically conductive layer 134 in such a way that portions of electrically conductive layer 134 around each of diodes 126 are electrically insulated from other portions of electrically conductive layer 134 around the other diodes 126. In other words, this etching may be implemented in such a way that the remaining portions of electrically conductive layer 134 are electrically insulated from one pixel to the other while keeping an electrical contact, for the remaining portions of layer 134, around each diode 126, with one of the second electrodes 108. In the described example of embodiment, the etched portions of electrically conductive layer 134 (designated with reference 135 in FIG. 6) are located on the bottom walls of trenches 130. In the described example, this etching is carried out in such a way that the portions of the electrically conductive layer 134 located in trench 131 are not etched and the electrical contact with the third electrode 111 is maintained. As a variant, it is possible for the portions of the electrically conductive layer 134 located in trench 131 to be etched. The structure obtained at this stage of the method is shown in FIG. 6.

In the described example of embodiment, dielectric layer 136 is then deposited on electrically conductive layer 134, and also on the portions of the bottom walls of trenches 130 which are no longer covered with electrically conductive layer 134 (that is, at the locations of the etched portions 135). A local etching may then be carried out to remove the portion of the dielectric layer 136 covering the bottom wall of trench 131, so that the electrically conductive layer 134 remains electrically accessible from the bottom of trench 131. The structure obtained at this stage of the method is shown in FIG. 7.

In the described example of embodiment, electrically conductive portions 138 are then formed so that they fill the remaining volume of trenches 130, 131 not occupied by the other previously-deposited layers. According to an example, the forming of portions 138 may comprise the deposition of layers of Ti/TiN/Cu, from which an electrochemical growth of copper is then implemented.

A planarization of the upper surface of the structure may then be implemented, with a stop on the second semiconductor layer 122. This chemical-mechanical polishing enables to remove dielectric hard mask 146, as well as the portions of layers 134 and 136 and the portions 138 arranged level with dielectric hard mask 146. The structure obtained at this stage of the method is shown in FIG. 8.

In the described example of embodiment, a dielectric encapsulation layer 140 is then deposited on the upper surface of the formed structure, this layer 140 then being locally etched to remove the portions of this layer covering electrically conductive portions 138 and second semiconductor layer 122. The remaining portions of this encapsulation layer form dielectric portions 140.

In the described example of embodiment, the electrically conductive and optically transparent layer 142 is then deposited on the upper surface of the resulting structure, thus forming the electrical contacts between the portions of the second semiconductor layer 122 of the diodes 126 and the electrically conductive portions 138, and also with the electrically conductive portion 138 which is in contact with the third electrode 111 corresponding to the common cathode of diodes 126. The structure obtained at this stage of the method is shown in FIG. 9.

Device 100 may then be completed by implementing an electrical/chemical passivation deposition and by forming connection pads, including connection pad 144 used as a contacts for the common cathode of device 100. The obtained device 100 corresponds to that shown in FIG. 1. As a variant, other connection pads coupled to the anodes and/or to the second electrodes 128 may also be formed via a routing through the metallization levels of the circuit.

In the example of embodiment of the device 100 previously described in relation with FIG. 1, all the diodes 126 of the device correspond to LEDs. As a variant, it is possible for at least part of these diodes 126 to correspond to photodiodes. In this case, active area 124 may comprise one or a plurality of receiver, that is, optically absorbing, layers.

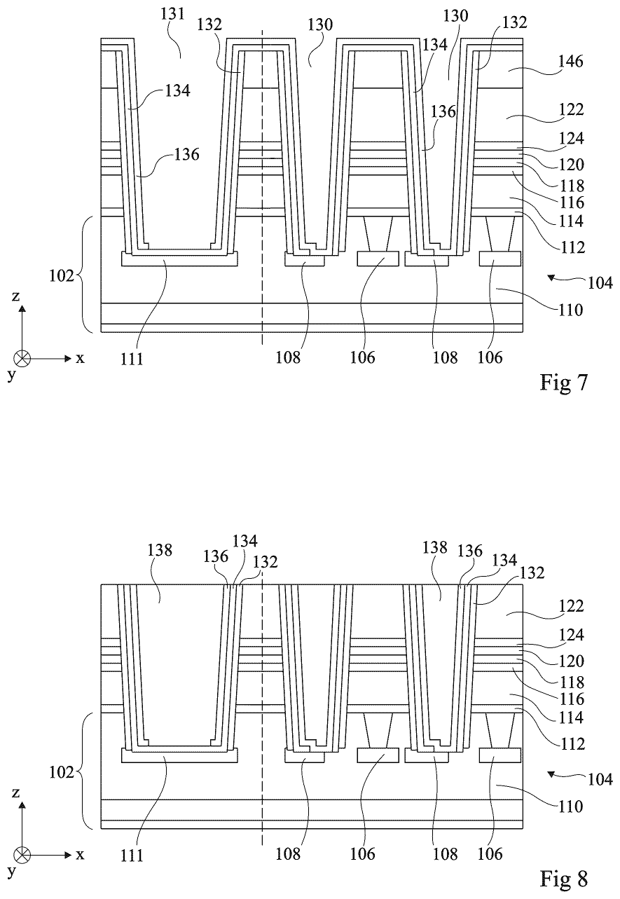

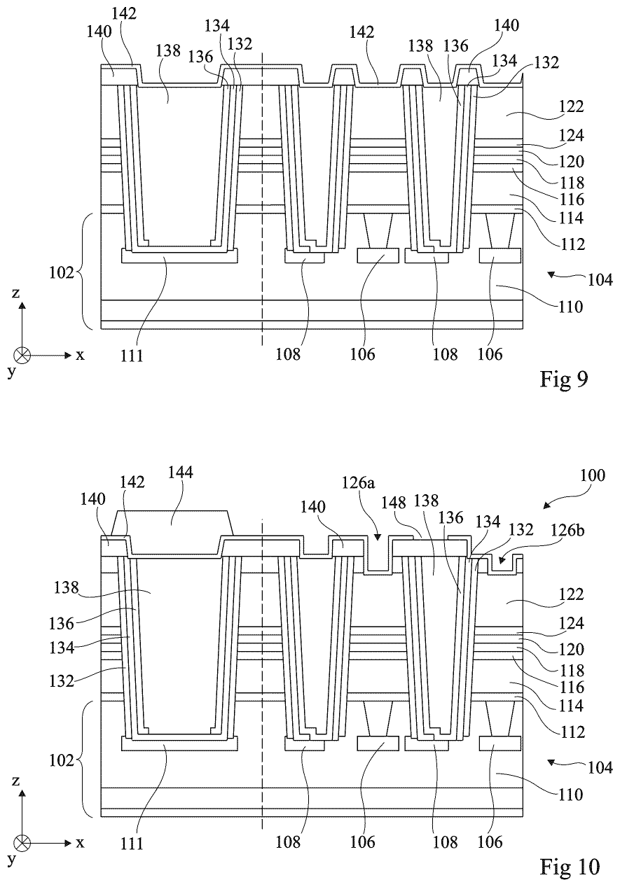

An example of an optoelectronic device 100 according to a second embodiment is described hereafter in relation with FIG. 10.

In this second embodiment, device 100 comprises certain diodes 126 corresponding to LEDs and other diodes 126 corresponding to photodiodes. In FIG. 10, the diode designated with reference 126a corresponds to a LED and is similar to the diodes 126 of the device 100 according to the first previously-described embodiment. Thus, the portion of the second semiconductor layer 122 of this diode 126a is electrically coupled to one of the electrically conductive portions 138 adjacent to this portion of the second semiconductor layer 122 so that it is coupled to the common cathode of the LEDs of device 100. Further, an electrical potential different from the electrical potentials applied to the anode and the cathode of this diode 126a is intended to be applied to the gate of this diode 126a formed by the portions of electrically conductive layer 134 arranged around the semiconductor stack of this diode 126a.

In the example of FIG. 10, the diode designated with reference 126b corresponds to a photodiode which differs from diode 126a in that the electrical potential intended to be applied to the portion of the second semiconductor layer 122 of this photodiode 126b does not correspond to that of the common cathode but to that intended to be applied to the gate of this diode 126b formed by the portions of the electrically conductive layer 134 arranged around the semiconductor stack of this diode 126b. This configuration of diode 126b is obtained due to the fact that the dielectric portion 140 formed next to this diode 126b covers electrically conductive portion 138 and not one of the portions of the electrically conductive layer 134 arranged around the semiconductor stack of this diode 126b. Thus, the portion of the electrically conductive and optically transparent layer 142 formed above this diode 126b electrically couples the portion of the second semiconductor layer 122 of this diode 126b to one of the portions of electrically conductive layer 134 arranged around the semiconductor stack of this diode 126b. Further, in this configuration, electrically conductive layer 142 is not continuous but is interrupted (interruption designated with reference 148 in FIG. 10) so that the portions of layer 134 providing electrical connections for the diodes corresponding to LEDs are not electrically coupled to those providing electrical connections for the diodes corresponding to photodiodes.

In this second embodiment, electrically conductive and optically transparent layer 142 enables to differentiate the electrical potential applied to the portions of second semiconductor layer 122 according to the nature of diodes 126. Thus, for diodes 126 corresponding to photodiodes, it is possible to apply to the portions of the second semiconductor layer 122 of these photodiodes the same electrical potential as that applied to the anodes of diodes 126 corresponding to LEDs. Thus, circuit 102 does not have to deliver opposite voltages to the LEDs and to the photodiodes of device 100, given that the same voltage can be used for the biasing of the LEDs and of the photodiodes.

In a specific configuration, device 100 may comprise an array of pixels such that each pixel of the array comprises a first diode similar to diode 126a and corresponding to a LED, and a second diode similar to diode 126b and corresponding to a photodiode. Each pixel of such an array thus fulfils both a light-emitting and a light-receiving function.

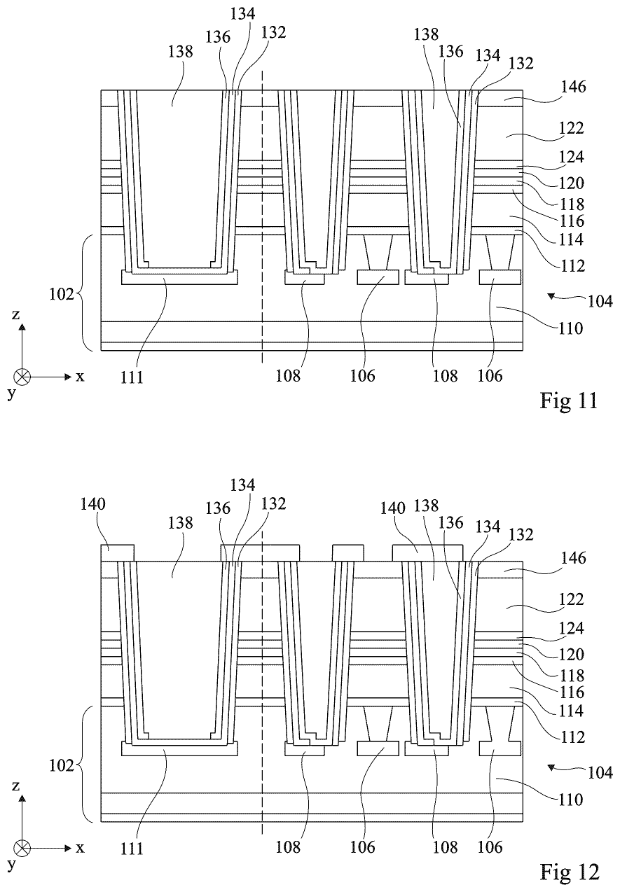

An example of a method of forming device 100 according to the second embodiment is described hereafter in relation with FIGS. 11 to 14.

The steps previously described in relation with FIGS. 2 to 8 are first carried out, with the difference, however, that the planarization of the upper surface of the resulting structure is implemented with a stop not on the second semiconductor layer 122 but on dielectric hard mask 146. The structure obtained at this stage of the method is shown in FIG. 11.

The dielectric encapsulation layer is then deposited on the upper surface of the obtained structure. This layer is then locally etched, for example via a photolithography, in order to remove, at the level of the diodes 126a intended to form LEDs, the portions of this layer covering electrically conductive portions 138 and dielectric hard mask 146, and to remove, at the level of the diodes 126b intended to form photodiodes, the portions of this layer covering the portions of the electrically conductive layer 134 and dielectric hard mask 146. In the case of diodes 126 intended to form photodiodes, a sufficiently large thickness of dielectric layer 136, corresponding for example to a SiO₂ layer having a thickness equal to approximately 200 nm, facilitates the implementation of this etching so as to etch the portions of the encapsulation layer located on the portions of the electrically conductive layer and to keep those located on electrically conductive portions 138. The remaining portions of this encapsulation layer form dielectric portions 140. The structure obtained at this stage of the method is shown in FIG. 12.

A second photolithography and etch step is then implemented to form openings 149 through dielectric hard mask 146, enabling to access the portions of the second semiconductor layer 122 of diodes 126a and 126b. The structure obtained at this stage of the method is shown in FIG. 13.

The electrically conductive and optically transparent layer 142 is then deposited on the upper surface of the obtained structure, thus forming the electrical contacts between the portions of the second semiconductor layer 122 and electrically conductive portions 138 for the diodes 126a corresponding to LEDs, and the electrical contacts between the portions of the second semiconductor layer 122 and the portions of electrically conductive layer 134 for the diodes 126b corresponding to photodiodes. Steps of photolithography and etching of electrically conductive layer 142 may then be implemented so that electrically conductive layer 142 is interrupted so that the portions of this layer 142 providing electrical connections for diodes corresponding to LEDs are not electrically coupled to those providing electrical connections for diodes corresponding to photodiodes. The structure obtained at this stage of the method is shown in FIG. 14.

Device 100 may be completed as previously described for the first embodiment, the obtained device 100 corresponding to that shown in FIG. 10.

In the examples of embodiment of the previously-described device 100, the third electrode 111 forms a cathode common to all the diodes 126 corresponding to LEDs. Further, in these examples, the third electrode 111 is arranged at an edge of device 100, for example next to the array of diodes 126.

In a first variant that can apply to the first or to the second previously-described embodiment, it is possible for each first electrode 106 to be arranged between two second electrodes 108 to which are electrically coupled the portions of electrically conductive layer 134 located around the diode 126 having the portion of its first semiconductor layer 120 electrically coupled to said first electrode 106. Further, in this first variant, device 100 may comprise a plurality of third electrodes 111 arranged in metallization level 104, each of the third electrodes 111 being electrically coupled to one of the electrically conductive portions 138 and arranged between two second electrodes 108 each electrically coupled to portions of electrically conductive layer 134 located around different diodes 126.

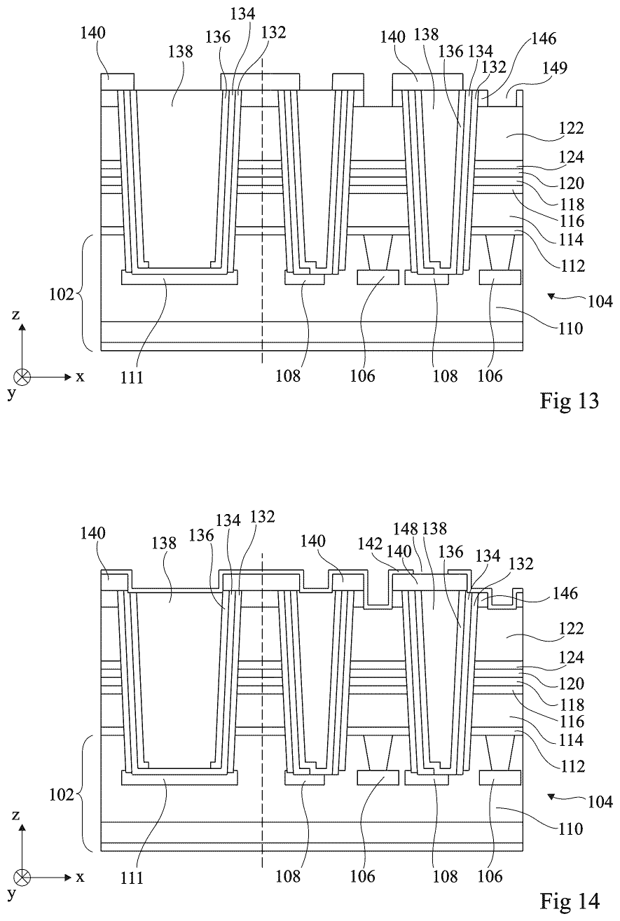

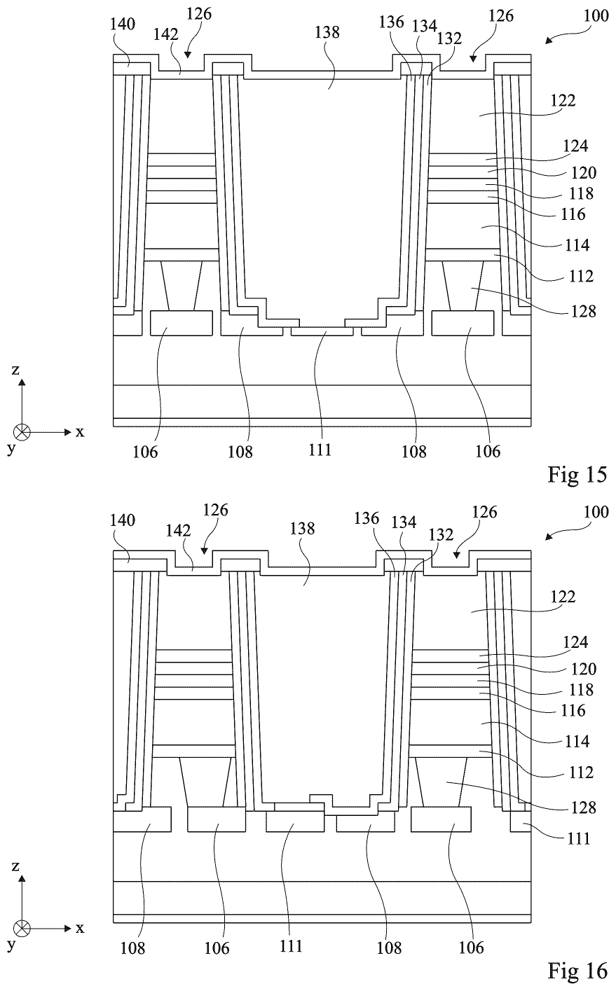

An example of a portion of a device 100 according to such a variant here applied to the device 100 according to the first embodiment is shown in FIG. 15. As can be seen in this drawing, the portions of electrically conductive layer 134 and of dielectric layer 136 located on the bottom walls of trenches 130 and covering the third electrodes 111 are etched so that electrically conductive portions 138 are in electrical contact with the third electrodes 111. Further, the portions of the electrically conductive layer 134 arranged in a same trench are electrically coupled to second electrodes 108 different from one another.

This first variant may facilitate the forming of device 100, with however as a counterpart a lower compactness of the device 100 thus formed as compared with a device 100 comprising a single third electrode 111 located at the edge of device 100.

In a second variant that can apply to the first or to the second previously-described embodiments, it is possible for device 100 to comprise a plurality of third electrodes 111, each electrically coupled to one of the electrically conductive portions 138 and arranged in metallization level 104, each of the first electrodes 106 being arranged between one of the second electrodes 108 and one of the third electrodes 111, and each of the third electrodes 111 is arranged between one of the first electrodes 106 and one of the second electrodes 108.

An example of such a second variant here applied to the device 100 according to the first embodiment is shown in FIG. 16. As can be seen in this drawing, electrically conductive layer 134 and dielectric layer 136 are etched in such a way that one of the portions of electrically conductive layer 134 is in electrical contact with the second electrode 108 located at the bottom of trench 130 and the electrically conductive portion 138 is in contact with the third electrode 111 located at the bottom of trench 130. Further, in the example of FIG. 16, a portion of electrically conductive layer 134 may be kept on the third electrode 111, electrically conductive portion 134 being electrically coupled to the third electrode 111. As a variant, this portion of electrically conductive layer 134 may be removed.

Like the first variant, this second variant enables to facilitate the forming of device 100, with however as a counterpart a lower compactness than when device 100 comprises a single third electrode 111 located at the edge of device 100.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. Optoelectronic device comprising at least:
a plurality of diodes, each comprising a portion of a stack of at least a first and a second semiconductor layers doped according to opposite conductivity types, a portion of the first semiconductor layer of each diode being electrically coupled to a first electrode arranged under said portion of the first semiconductor layer;
trenches running through the stack, separating the diodes from one another and from which second electrodes are electrically accessible;
an electrically conductive layer arranged at least against side walls of the trenches, electrically insulated from the stack, electrically coupled to the second electrodes and which is interrupted in such a way that portions of the electrically conductive layer arranged around each of the diodes are electrically insulated from other portions of the electrically conductive layer arranged around the other diodes;
electrically conductive portions arranged in the trenches, electrically insulated from the electrically conductive layer and electrically coupled to one another and to at least a third electrode;
and wherein bottom walls of the trenches are at least partly formed by the second electrodes.

2. Optoelectronic device according to claim 1, wherein the electrically conductive layer is interrupted at bottom walls of the trenches.

3. Optoelectronic device according to claim 1, wherein the electrically conductive portions are electrically coupled to the portions of the second semiconductor layer of at least part of the diodes corresponding to LEDs.

4. Optoelectronic device according to claim 3, wherein the electrically conductive portions are electrically coupled to the portions of the second semiconductor layer of the LEDs by at least one electrically conductive and optically transparent layer arranged on the stack and on the electrically conductive portions.

5. Electronic device according to claim 4, wherein the electrically conductive and optically transparent layer is electrically insulated from the electrically conductive layer by dielectric portions arranged between the electrically conductive layer and the electrically conductive and optically transparent layer.

6. Optoelectronic device according to claim 1, wherein the electrically conductive portions are electrically insulated from the electrically conductive layer by at least a first dielectric layer arranged between the electrically conductive portions and the electrically conductive layer.

7. Optoelectronic device according to claim 1, wherein the third electrode is arranged at an edge of the optoelectronic device.

8. Optoelectronic device according to claim 1, wherein:
each first electrode is arranged between two second electrodes to which are electrically coupled the portions of the electrically conductive layer located around the diode having the portion of its first semiconductor layer electrically coupled to said first electrode, and
the optoelectronic device comprises a plurality of third electrodes, each electrically coupled to one of the electrically conductive portions and arranged between two second electrodes, each electrically coupled to portions of the electrically conductive layer located around different diodes.

9. Optoelectronic device according to claim 1, comprising a plurality of third electrodes, each electrically coupled to one of the electrically conductive portions, each of the first electrodes being arranged between one of the second electrodes and one of the third electrodes, and each of the third electrodes is arranged between one of the first electrodes and one of the second electrodes.

10. Optoelectronic device according to claim 1, wherein the portions of the electrically conductive layer arranged around at least part of the diodes corresponding to photodiodes are electrically coupled to the portions of the second semiconductor layer of the photodiodes.

11. Optoelectronic device according to claim 10, wherein the portions of the electrically conductive layer arranged around the photodiodes are electrically coupled to the portions of the second semiconductor layer of the photodiodes by at least one electrically conductive and optically transparent layer arranged on the stack and on the portions of the electrically conductive layer arranged around the photodiodes.

12. Optoelectronic device according to claim 1, further comprising a second dielectric layer arranged between the electrically conductive layer and the stack.

13. Method of manufacturing an optoelectronic device, comprising at least the steps of:
forming of a stack of at least a first and a second semiconductor layers doped according to opposite conductivity types;
creation of trenches running through the stack, separating from one another diodes, each comprising a portion of the stack and providing access to second electrodes such that bottom walls of the trenches are at least partly formed by the second electrodes, a portion of the first semiconductor layer of each diode being electrically coupled to a first electrode arranged under said portion of the first semiconductor layer;
forming of an electrically conductive layer arranged at least against side walls of the trenches, electrically insulated from the stack, electrically coupled to the second electrodes and which is interrupted in such a way that portions of the electrically conductive layer arranged around each of the diodes are electrically insulated from the portions of the electrically conductive layer located around the other diodes;
implementation of electrically conductive portions arranged in the trenches, electrically insulated from the electrically conductive layer and electrically coupled to one another and to at least a third electrode.
